(19) United States
(12) Patent Application Publication
(10) Pub. No.: US 2015/0349705 A1
(43) Pub. Date: Dec. 3, 2015

(54) Method for Improving Photovoltaic Cell Efficiency

(71) Applicant: Robert Edward Sandstrom, Longview, WA (US)

(72) Inventor: Robert Edward Sandstrom, Longview, WA (US)

(21) Appl. No.: 14/806,507

(22) Filed: Jul. 22, 2015

Related U.S. Application Data
(63) Continuation of application No. 14/599,879, filed on Jan. 19, 2015.
(60) Provisional application No. 61/966,177, filed on Feb. 18, 2014.

(51) Int. Cl. H01L 31/042

(52) U.S. Cl. CPC H02S 40/00; H01L 31/042

(57) ABSTRACT

A method of generating electricity from light, that uses a photovoltaic array, that includes a junction between an inorganic electron-donating layer and an inorganic electron-accepting layer. The electron-donating layer includes moieties which after photon activation have unpaired electrons, and wherein some of the electrons are freed when light strikes the electron-donating layer, thereby transforming the moieties into free radicals or equivalents but many of the freed electrons recombine. Also, many of the free radicals or equivalents in the triplet state are optimally responsive to a selective magnetic field that has been determined to optimally increase the lifetime of the triplet state of the free radicals and thereby forestall recombination of the freed electrons into the free radicals. A magnetic field of substantially the optimal strength that is substantially unvarying over the electron donating layer is created as the array is being exposed to light.

### RELATED APPLICATIONS

This application is a continuation of application Ser. No. 14/599,879 filed Jan. 19, 2015, which, in turn, claims priority from provisional application No. 61/966,177, filed Feb. 18, 2014, which are also incorporated by reference as if fully set forth herein.

### BACKGROUND

Many different types of photo-voltaic cells have been developed, including crystalline silicon, thin film and multi-junction cells. Although these differing types of cells work along broadly similar principles, with photoactive compounds absorbing energy from photons leading to the production of electric power, the specifics vary broadly. In terms of commercialization, as of 2014, crystalline silicone cells were dominant.

Another type of photovoltaic cell, in development as of 2014, was the bulk heterojunction polymer photovoltaic cell. This type of cell included a polymer thin film having an interpenetrating network of a conjugated polymer donor such as poly(3-hexylthiophene-2,5-diyl) (P3HT) and a soluble fullerene acceptor which is typically [6,6]-phenyl-C61-butyric acid methyl ester (PCBM) as the photoactive layer. It has been observed, for this type of cell that the triplet state exitons were far more numerous and longer lasting than singlet state exitons. Accordingly, it was found that creating a weak magnetic field in the thin film had the effect of lowering the short-circuit current by increasing the population of triplet state exitons. W. F. Zhang, Y. Xu, H. T. Wang, C. H. Xu, S. F. Yang, Sol. Energy Mater. Sol. Cells 95(2011) 2880.

The experimenters who authored the above noted paper, however, took this result to be intimately tied to the exact nature of bulk heterojunction polymer cells, and they do not ever suggest that the result might be broadly generalizable.

Later, another group of researchers experimented with differing magnetic field strengths applied to dye-sensitized TᵢO₂ nanoparticle-based photovoltaic cells.

Although power conversion efficiency was improved, it does not appear that the mechanism was the same as for the earlier experiment. The improvement in the J_{sc} and g observed in the low magnetic field was attributed to slow electron recombination predominantly caused by the variations of the local electronic surface properties of TᵢO₂. Magnetic-field enhanced photovoltaic performance of dye-sensitized TᵢO₂ nanoparticle-based solar cells Fengshi Cai, Shixin Zhang, Shuai Zhou, Zhihao Yuan.

Notably, both of these groups experimented and published results regarding photovoltaic cells that were largely made of an organic colloidal suspension or gel. Researchers far more readily view material of this sort from the point of view of chemistry, as this type of material can be probed and sampled fairly easily, thereby permitting an investigator to gather information regarding the internal dynamics of the material.

Further, the vast bulk of photo-voltaic cells in commercial operation are not of the types discussed in the articles. Accordingly, the types of photo-voltaic cells that represent the bulk of the commercial market are left without any benefit from the work of these researchers.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

In a first separate aspect, the present invention may take the form of a method of generating electricity from light that uses a photovoltaic array that includes a junction between an inorganic electron-donating layer, and an inorganic electron-accepting layer. The electron-donating layer includes moieties having paired electrons in orbital shells, and wherein some of the electrons are freed from the orbital shells when light strikes the electron-donating layer, thereby transforming the moieties into free radical equivalents but many of the freed electrons recombine back into the orbital shells. Also, many of the free radical equivalents enter a triplet state, and are optimally responsive to an selected magnetic field that has been determined to optimally increase the lifetime of the triplet state and thereby forestall recombination of the freed electrons into the free radical equivalents. A magnetic field of substantially the optimal strength that is substantially unvarying over the electron donating layer is created.

In a second separate aspect, the present invention may take the form of a photovoltaic electric generation assembly includes a photovoltaic array that includes a junction between an inorganic electron-donating layer, and an inorganic electron-accepting layer. The electron-donating layer includes moieties having unpaired electrons in orbital shells, and wherein some of the electrons are freed from the orbital shells when light strikes the electron-donating layer, thereby transforming the moieties into free radical equivalents but many of the freed electrons recombine back into the orbital shells. Also, many of the free radical equivalents enter a triplet state, and are optimally responsive to an optimal magnetic field that has been determined to optimally increase the lifetime of the triplet state and thereby forestall recombination of the freed electrons into the free radicals. Also, a magnetic assembly, exterior to the photovoltaic array creates a magnetic field of the optimal strength that is substantially unvarying over the electron-donating layer.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced drawings. It is intended that the embodiments and figures disclosed herein are to be considered illustrative rather than restrictive.

FIG. 1 is a front view of a photovoltaic assembly, according to the present invention.

FIG. 2A is an illustration of the operation of a photovoltaic cell, in the absence of magnetic field effects.

FIG. 2B is an illustration of the operation of a photovoltaic cell, in the presence of magnetic field effects.

### DETAILED DESCRIPTION OF THE PREFERRED EMBODIMENTS

Many photovoltaic cells function by having an electron-donating layer made of a material. When struck by a photon of correct energy an electron is freed, thereby creating a potential flow of electricity. But the electron and the moiety from which it has been freed are likely to recombine, ending this process. When the electron-donating layer is a solid, the terminology used to describe the phenomenon of the freed electron and the moiety now missing an electron, having its origin in solid state research, is “active electron” and “hole” often referred to as an “exciton.” Terminology varies but when an entity is produced that has an unpaired orbital electron and a free electron, the system is the equivalent of a free radical and a freed electron and is termed a “free radical equivalent” herein.

It is possible for a liquid, colloidal suspension or a gel to demonstrate that the “hole” actually displays the same characteristics, in terms of magnetic precession, as a free radical. In fact, what has been termed a “hole” in solid state research is a “free radical” but has simply not heretofore been recognized as such. Accordingly, a magnetic field that acts to forestall the recombination of free radicals with active electrons will increase the quantity of free electrons available for transport and therefore the efficiency of the photovoltaic cell. In particular a magnetic field that maintains free radicals in the triplet state, which greatly reduces the chance of recombination, will increase the number of active electrons and increase the efficiency of the photovoltaic cell.

Each particular material will respond optimally to a magnetic field of optimal strength for maintaining free radicals in the triplet state. Some of the research referenced in the Background section involved the mixing of magnetic particles into a photosensitive layer. This naturally causes a magnetic field that varies with range to the nearest magnetic particle. A magnetic field at the optimal strength that does not vary significantly over the expanse of the electron-donating layer of photosensitive material will yield a greater increase in photovoltaic cell efficiency.

The vast bulk of photo-voltaic cells in operation as of 2014 include an electron-donating layer comprising a silicon based material, such as monocrystalline silicon, polycrystalline silicon (including ribbon silicon) or amorphous silicon. Other materials placed in commercial use, in thin film structures in which the thickness of the electron-donating layer is less than 40 μm and could be as thin as 2 nm, include cadmium telluride (CdTe), copper indium gallium diselenide (CIGS). Amorphous silicon and crystalline silicon is also used in thin film applications.

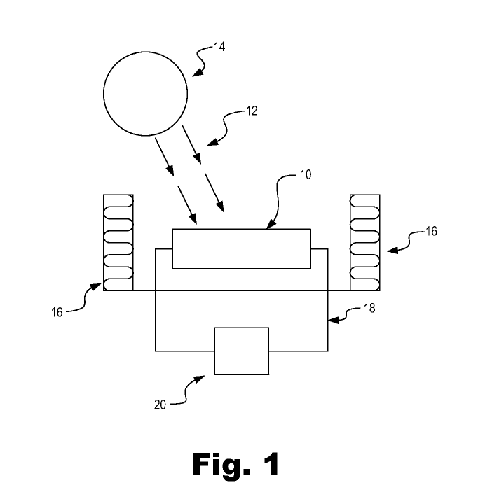

Referring to FIG. 1, a photovoltaic cell 10, is exposed to photons (light) 12, from the sun 14 and simultaneously exposed to a uniform magnetic field produced by a Helmholtz coil or array of such coils. 16. Electrons produced the photovoltaic cell are connected by an electric circuit 18, to an electric load 20, which may be, more specifically, an electric storage device. In the alternative a balanced arrangement of permanent magnets or a solid layer of such magnets may replace the Helmholtz coils 16, to achieve a similar effect.

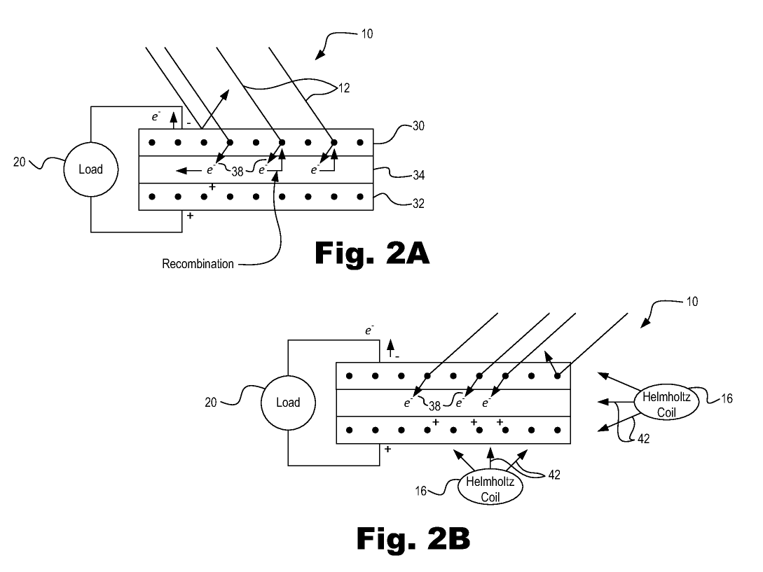

FIGS. 2A and 2B illustrate the effect of the magnetic field on the activity of freed electrons. In FIG. 2A, a photovoltaic cell 10 includes an electron-donating layer 30 is joined to an electron-accepting layer 32 by a junction 34 (shown in greatly expanded form) where the process is unaffected by a magnetic field, photons 12 striking the n-type semiconductor free three electrons 38 (as an illustration) into the junction 34. One of these flows to the load 20, thereby forming a part of the current produced by the cell 10. But the other two recombine into the electron-donating layer (shortly after forming), typically into the same moiety from which the particular electron 38 originated. As shown in FIG. 2B, in the same photovoltaic cell the magnetic field 42 (generated from Helmholtz coils 16 shown in completely conceptual form) prevents some of the electrons 38 from recombining back into the moiety from which they came, so they join the flow to the load 20. Skilled persons will understand that this is merely an illustration, and that in reality even with the magnetic field, many electrons recombine into the moiety from which they were ejected. The magnetic field, however, by causing more free radicals to remain in the triplet state, prevents many recombinations, and thereby contributes to the flow of electricity.

In one set of embodiments electron-donating layer 30 and electron-accepting layer 34 are both made of similar material, such as crystalline silicon, but where electron donating layer 30 is n-type and electron-accepting layer 34 is p-type. If comprised of crystalline silicon, layers 30 and 34 may be either monocrystalline silicon or polycrystalline silicon. Alternatively layers 30 and 34 are comprised of amorphous silicon or a thin film material such as CdTe or CIGS. In an alternative set of embodiments, the electron-donating layer 30 is comprised of conjugated polymers and the electron-accepting layer 34 is comprised of inorganic nanocrystals.

For each one of the above recited materials, there is a corresponding magnetic field strength that will typically have a value of between 10 and 100 gauss (1 and 10 millitesla) that optimally extends the triplet state lifetimes in free radicals formed in the material.

To determine the optimal magnetic field strength is a fairly easy process, however. A simple experiment may be configured by taking a photovoltaic cell and placing it between two Helmholtz coils, as shown in FIG. 1. A light having known characteristics is then shined upon the photovoltaic cell and various magnetic field strengths are applied, with the resultant electric current produced by the photovoltaic cell measured. In one preferred method a time period wherein no magnetic field is applied is interspersed between the times when a magnetic field is applied, to eliminate the effect of the previous test for magnetic field effect.

While a number of exemplary aspects and embodiments have been discussed above, those possessed of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

1. A method of generating electricity from light, comprising:
(a) providing a photovoltaic array, including a junction between an inorganic electron-donating layer, and an inorganic electron-accepting layer, and wherein said electron-donating layer includes moieties having unpaired electrons in orbital shells, and wherein some of said electrons are freed from said orbital shells when light strikes said electron-donating layer, thereby transforming said moieties into free radical equivalents, but wherein many of said freed electrons recombine back into said orbital shells; also, many of said free radical equivalents enter triplet state, said triplet state free radicals being optimally responsive to a magnetic field having an optimal strength that has been determined to optimally increase the lifetime of said triplet state of said free radicals and thereby forestalls recombination of said freed electrons into said free radicals;
(b) providing a magnetic assembly, exterior to said photovoltaic array; and
(c) creating a magnetic field of substantially said optimal strength, that is substantially unvarying over said electron donating layer, as said array is being exposed to light.

2. The method of claim 1, wherein said electron-donating layer comprises crystalline material.

3. The method of claim 2, wherein said crystalline material, is crystalline silicon.

4. The method of claim 3, wherein said crystalline silicone is polycrystalline silicon.

5. The method of claim 4, wherein said polycrystalline silicon is ribbon silicon.

6. The method of claim 3, wherein said crystalline silicon is monocrystalline silicon.

7. The method of claim 1, wherein said electron-donating layer comprises amorphous silicon.

8. The method of claim 1, wherein said electron-accepting layer is comprised of nanocrystals.

9. The method of claim 1, wherein said magnetic assembly comprises two Helmholtz coils, spaced in symmetric fashion about said photovoltaic array.

10. The method of claim 1, further including a step of repeatedly varying an applied magnetic field strength and measuring a resultant current produced by said photovoltaic array, prior to performing the step of paragraph (c), in order to determine said optimal magnetic field strength.

11. A photovoltaic driven electric generation assembly, comprising:
(a) a photovoltaic array that includes a junction between an inorganic electron-donating layer and an inorganic electron-accepting layer, and wherein said electron-donating layer includes moieties having unpaired electrons in orbital shells, and wherein some of said electrons are freed from said orbital shells when light strikes said electron-donating layer, thereby transforming said moieties into free radical equivalents, but wherein many of said freed electrons recombine back into said orbital shells, many of said free radical equivalents entering triplet state, said triplet state being optimally responsive to a magnetic field having an optimal strength that optimally increases the lifetime of said triplet state of said free radicals and thereby forestalls recombination of said freed electrons into said free radicals; and
(b) a magnetic assembly, exterior to said photovoltaic array that creates a magnetic field of said optimal strength, that is substantially unvarying over said electron-donating layer.

12. The assembly of claim 11, wherein said electron-donating layer comprises crystalline silicon.

13. The assembly of claim 12, wherein said crystalline silicone is polycrystalline silicon.

14. The assembly of claim 13, wherein said polycrystalline silicon is ribbon silicon.

15. The assembly of claim 12, wherein said crystalline silicon is monocrystalline silicon.

16. The assembly of claim 11, wherein said electron-donating layer comprises amorphous silicon.

17. The assembly of claim 11, wherein said magnetic assembly comprises two Helmholtz coils, spaced in symmetric fashion about said photovoltaic array.
